(19) United States
(12) Patent Application Publication
(10) Pub. No.: US 2025/0269543 A1
(43) Pub. Date: Aug. 28, 2025

(54) APPARATUS FOR SUPPLYING AND RECOVERING COLLETS AND EJECTOR HOODS

(71) Applicant: FLC, Cheonan-si (KR)

(72) Inventors: Ganghyun MUN, Cheonan-si (KR); Sunghee CHO, Asan-si (KR)

(21) Appl. No.: 19/015,627

(22) Filed: Jan. 9, 2025

(30) Foreign Application Priority Data
Jan. 10, 2024 (KR) 10-2024-0004101

(51) Int. Cl. B25J 15/04; B25J 11/00; B25J 15/06; B25J 19/00

(52) U.S. Cl. CPC B25J 15/0441; B25J 15/0666; B25J 19/0066; B25J 11/0095

(57) ABSTRACT

The present disclosure relates to an apparatus for supplying and recovering collets and ejector hoods. According to the embodiment of the present disclosure, the apparatus includes a cabinet unit configured to accommodate a collet and an ejector hood, a mounting robot configured to withdraw the ejector hood accommodated in the cabinet unit and mount the withdrawn ejector hood on an ejector, and a replacement robot configured to withdraw the collet accommodated in the cabinet unit and replace the withdrawn collet.

### CROSS-REFERENCE TO RELATED APPLICATION

This application claims priority to Korean Patent Application No. 10-2024-0004101, filed on Jan. 10, 2024, which is incorporated herein by reference in its entirety.

### BACKGROUND

### Technical Field

The present disclosure relates to an apparatus for supplying and recovering collets and ejector hoods, the apparatus being capable of automatically replacing collets and ejector hoods in die bonding equipment.

### Related Art

In general, a die bonding process refers to a process for bonding dies, which are individualized by a sawing process, onto substrates. During the die bonding process, an ejector may be used to eject dies from a wafer, and a pick-up unit may be used to pick up the dies and transfer the dies.

The pick-up unit may include a collet configured to pick up the die by using a vacuum, a pick-up head to which the collet is coupled, and a drive part configured to move the pick-up head.

The collet may be required to be replaced when the collet is abraded as the collet is used over a long period of time or when the collet needs to suck dies with different sizes. In the related art, in order to change collets, a collet is inserted or loaded into a collet accommodation groove formed in a panel, a collet coupled to the pick-up head is removed by using a catching member provided on the panel, and the collet on the panel is coupled to the pick-up head by a magnetic force.

When all the collets loaded in advance onto the panel are used, the die bonding process is stopped, and then new collets are supplied onto the panel. In addition, the removed collets may be recovered in the state in which the die bonding process is stopped. Because the die bonding process is frequently stopped to supply new collets and recover the replaced collets, the productivity of the die bonding process may deteriorate.

A hood may be required to be replaced to eject dies with different sizes. Because the hood is replaced manually by an operator, a significant amount of time may be required for the operator to manually replace the hood. In addition, the die bonding process is also stopped during the process of replacing the hood, which may further degrade the productivity of the die bonding process.

The background technology of the present disclosure is disclosed in Korean Patent No. 10-1340831 (published on Dec. 11, 2013).

### SUMMARY

The present disclosure has been made in an effort to solve the above-mentioned problem, and an object of the present disclosure is to provide an apparatus for supplying and recovering collets and ejector hoods, the apparatus being capable of automatically replacing a collet and an ejector hood, which have been completely used, without stopping die bonding equipment.

An embodiment of the present disclosure provides a supplying/recovering apparatus including: a cabinet unit configured to accommodate a collet and an ejector hood; a replacement robot configured to withdraw the collet accommodated in the cabinet unit and replace the withdrawn collet; and a shutter spaced apart from a handle provided in a direction in which the cabinet unit is withdrawn.

The cabinet unit may include: a collet accommodation part configured to supply and recover the collet; an ejector hood accommodation part formed at one side of the collet accommodation part and configured to accommodate the ejector hood; a sliding movement part provided rearward of the collet accommodation part and the ejector hood accommodation part and configured to provide a sliding movement; and a sliding drive part formed below the collet accommodation part and the ejector hood accommodation part and configured to operate the sliding movement part.

The collet accommodation part may include: a collet recovery box configured to accommodate a used collet; and a collet cartridge spaced apart upward from the collet recovery box and configured to accommodate a non-used collet.

The collet recovery box may include: at least one support part configured to support a lower surface of the used collet; and a vertical movement part provided on a rear surface of the support part and configured to provide a vertical movement of the support part.

The support part may include: a bottom member; vertical members vertically formed on two opposite surfaces of the bottom member and having a width that decreases in a vertical direction; and an inclination member formed to have a predetermined angle toward the bottom member from a vertex of the vertical member.

The collet cartridge may include: an accommodation groove; a depressed portion having a predetermined size from centers of right and left surfaces of the accommodation groove; vertical depressed portions vertically formed on two opposite surfaces of the depressed portion; an inclination portion formed to have a gradient from an end of the vertical depressed portion; and a parallel portion formed to be parallel to a bottom surface from an end of the inclination portion.

The supplying/recovering apparatus may further include: curved portions respectively formed at vertices of the accommodation groove and curved in an outward direction of the accommodation groove.

The replacement robot may include a first replacement robot and a second replacement robot, the first replacement robot may withdraw the collet recovery box and provide the collet recovery box to the second replacement robot, and the second replacement robot may move a head upward, introduce a completely used collet into the collet recovery box, and provide the collet to the first replacement robot.

The first replacement robot may withdraw the collet cartridge, rotate the collet cartridge, and position the collet cartridge below the head, and when the collet with the collet cartridge is coupled to the head, the first replacement robot may introduce the collet cartridge into a position at which the collet cartridge is withdrawn.

The cabinet unit may include: a first base provided with the sliding movement part; and a second base to which the other side of the sliding movement part is coupled, and the sliding movement part may be provided as a plurality of sliding movement parts.

According to the present disclosure having the method and features, the collets and the ejector hoods may be changed without stopping the operating die bonding equipment or opening a door, thereby maintaining an operation rate of the die bonding equipment.

In addition, the collet and the ejector hood may be replaced in the state in which the cabinet on which the collet and the ejector hood are positioned protrudes to the outside of the die bonding equipment, such that the operator's body does not need to enter the equipment, which may prevent a risk of musculoskeletal diseases and the like.

### BRIEF DESCRIPTION OF THE DRAWINGS

FIG. 1 is a configuration view for explaining a supplying/recovering apparatus according to an embodiment of the present disclosure.

FIGS. 2 to 4 are views for explaining a cabinet unit according to the embodiment of the present disclosure.

FIG. 5 is a view for explaining a collet recovery box according to the embodiment of the present disclosure.

FIG. 6 is a view for explaining a collet cartridge according to the embodiment of the present disclosure.

FIG. 7 is a view for explaining a replacement robot according to the embodiment of the present disclosure.

FIG. 8 is a view for explaining a cabinet and a shutter according to the embodiment of the present disclosure.

### DETAILED DESCRIPTION

The present disclosure may be variously modified and may have various forms, and aspects (or embodiments) will be described in detail herein. However, the description of the exemplary embodiments is not intended to limit the present disclosure to the particular exemplary embodiments, but it should be understood that the present disclosure is to cover all modifications, equivalents and alternatives falling within the spirit and technical scope of the present disclosure.

The terms used in the present specification are used to just describe a specific aspect (or embodiment) and are not intended to limit the present disclosure. Singular expressions include plural expressions unless clearly described as different meanings in the context. In the present application, the terms “comprises,” “comprising,” “includes,” “including,” “containing,” “has,” “having” or other variations thereof are inclusive and therefore specify the presence of stated features, integers, steps, operations, elements, components, and/or combinations thereof, but do not preclude the presence or addition of one or more other features, integers, steps, operations, elements, components, and/or combinations thereof.

Unless otherwise defined, all terms used herein, including technical or scientific terms, have the same meaning as commonly understood by those skilled in the art to which the present disclosure pertains. The terms such as those defined in a commonly used dictionary should be interpreted as having meanings consistent with meanings in the context of related technologies and should not be interpreted as ideal or excessively formal meanings unless explicitly defined in the present application.

In this specification, the terms “first,” “second,” etc. are used only to distinguish different components, and are not dependent on the manufacturing order, and the names may not match in the detailed description of the present disclosure and the claims.

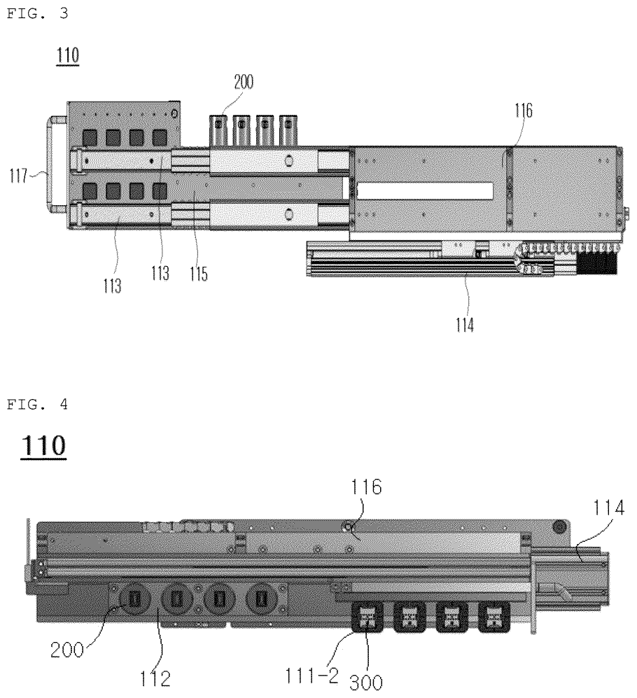

Prior to the description, for convenience of description in the present specification, the present disclosure will be described with reference to FIG. 2.

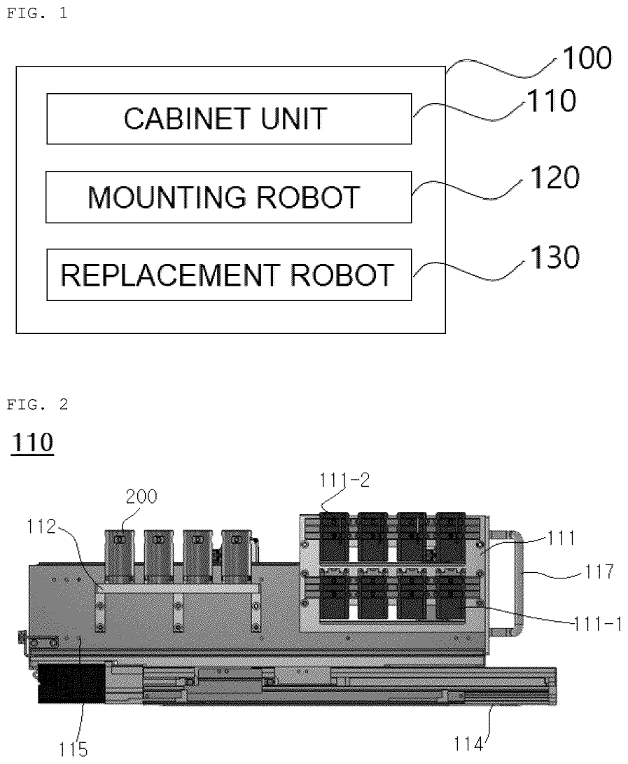

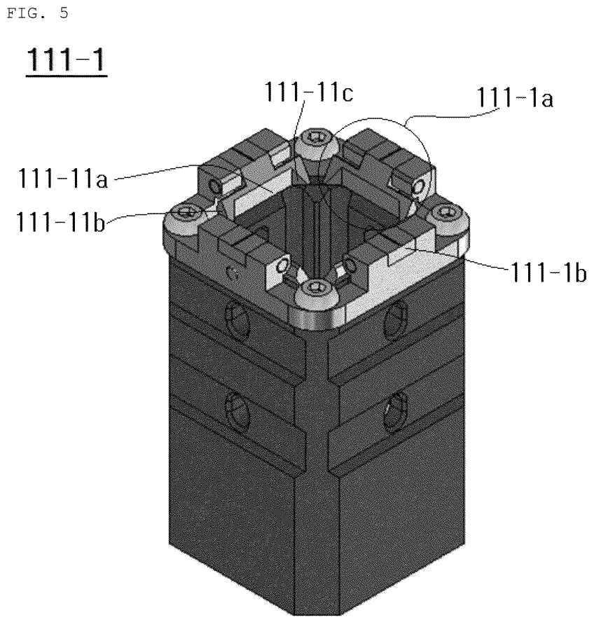

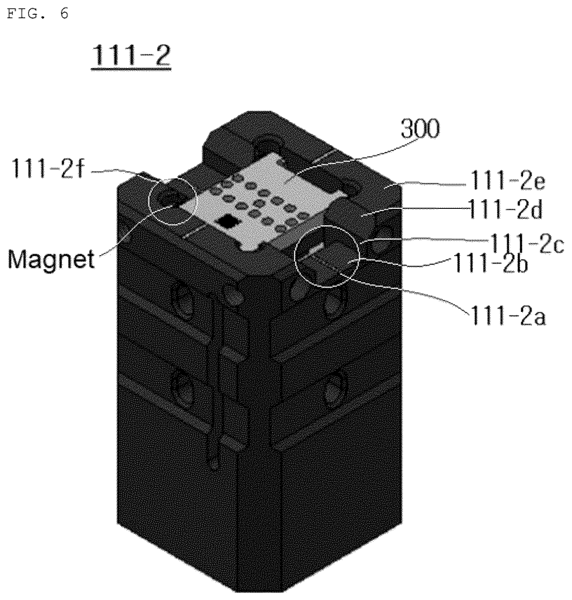

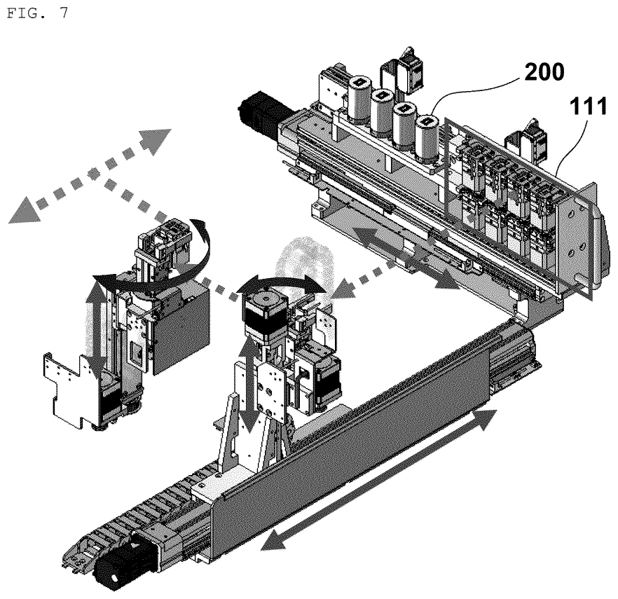

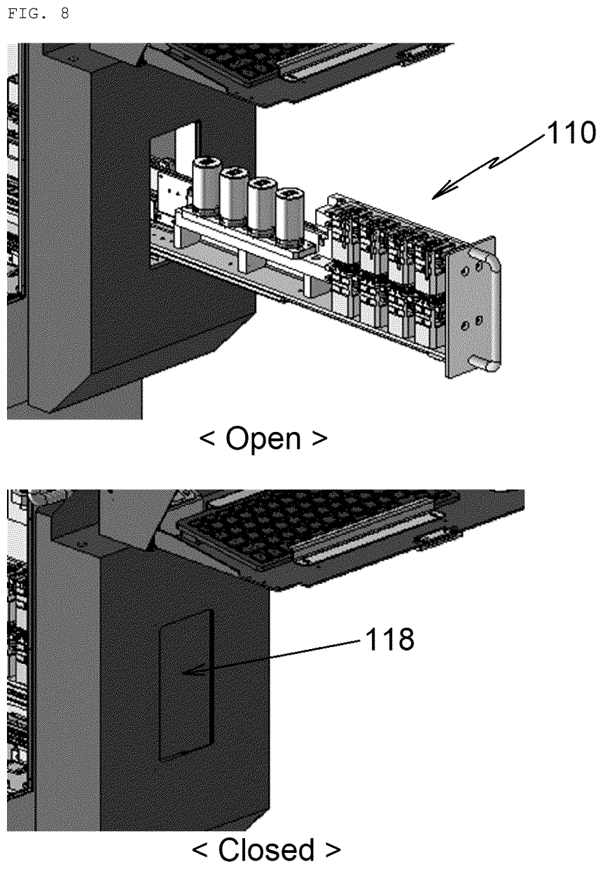

FIG. 1 is a configuration view for explaining a supplying/recovering apparatus according to an embodiment of the present disclosure, FIGS. 2 to 4 are views for explaining a cabinet unit according to the embodiment of the present disclosure, FIG. 5 is a view for explaining a collet recovery box according to the embodiment of the present disclosure, FIG. 6 is a view for explaining a collet cartridge according to the embodiment of the present disclosure, FIG. 7 is a view for explaining replacement robot according to the embodiment of the present disclosure, and FIG. 8 is a view for explaining a cabinet and a shutter according to the embodiment of the present disclosure.

First, a supplying/recovering apparatus 100 according to an embodiment of the present disclosure is coupled to die bonding equipment and used, and the supplying/recovering apparatus 100 is used to automatically replace an ejector 200 and a collet 300 that are being operated. As illustrated in FIG. 1, the supplying/recovering apparatus 100 according to the embodiment of the present disclosure includes a cabinet unit 110, a mounting robot 120, and a replacement robot 130.

First, the cabinet unit 110 includes a collet accommodation part 111, an ejector hood accommodation part 112, sliding movement parts 113, a sliding drive part 114, a first base 115, a second base 116, and a handle 117.

First, the collet accommodation part 111 includes collet recovery boxes 111-1 and collet cartridges 111-2. In this case, as illustrated in FIG. 2, the collet recovery box 111-1 according to the embodiment of the present disclosure is provided below the collet cartridge 111-2. The configuration in which a zone in which the collet recovery boxes 111-1 are positioned and a zone in which the collet cartridges 111-2 are positioned are separated as described above is used to sort used collets 300 and non-used collets 300. In case that the positions and zones are not separated, the used collet 300 may be coupled to a head 400 again, which may cause an erroneous operation of the die bonding equipment. The collet recovery box 111-1 and the collet cartridge 111-2 will be described below in detail with reference to FIG. 6.

Next, as illustrated in FIG. 2, the ejector hood accommodation part 112 is provided at a lateral side of the collet accommodation part 111, and ejector hoods 200 are positioned on the ejector hood accommodation part 112. In this case, in a state in which a plurality of non-used ejector hoods 200 are positioned, the ejector hood accommodation part 112 uses the non-used ejector hood 200 present at a position closest to the collet accommodation part 111. In this case, the ejector hood 200 is provided above an ejector used to separate a bonded micro-chip upward. The collet accommodation part 111 and the ejector hood accommodation part 112 are coupled to one side of the first base 115. In addition, the sliding movement parts 113 to be described below are provided on the first base 115 and provided at a side opposite to a side at which the collet accommodation part 111 and the ejector hood accommodation part 112 are installed. Further, one side of the sliding movement part 113 to be described below is coupled to the first base 115, and the other side of the sliding movement part 113 to be described below is coupled to the second base 116. Because the sliding movement part 113 is coupled as described above, the first base 115 may be moved by the sliding movement part 113 and move the collet accommodation part 111 and the ejector hood accommodation part 112. In addition, as illustrated in FIG. 3, the sliding movement parts 113 may move in one direction along rails. The sliding movement parts 113 may be provided as a plurality of sliding movement parts 113, as illustrated in FIG. 3. In this case, the configuration in which the plurality of sliding movement parts 113 are used may provide structural stability because of the weights of the collet recovery boxes 111-1 and the collet cartridges 111-2 and disperse a load of the sliding movement part 113 in comparison with a case in which only a single sliding movement part 113 is present.

Next, the sliding drive part 114 is provided below the second base 116 and slides the sliding movement part 113 so that the first base 115 moves along the rail on which the sliding movement part 113 is installed. In this case, the sliding drive part 114 may be moved by a motor or other power methods, and the present disclosure is not limited to the methods.

Further, the first base 115 and the second base 116 have the same size, and both the collet accommodation part 111 and the ejector hood accommodation part 112 are coupled to the first base 115.

Next, the handle 117 is used by a manager or user to replace the ejector hood 200 or the collet accommodation part 111 that has been completely used. The manager may easily move the supplying/recovering apparatus to the outside in a state in which the manager grasps the handle 117 with his/her hand in a state in which a shutter 118 to be described below is opened. Then, the manager may easily replace the ejector hood 200 or the collet accommodation part 111 that has been completely used.

Hereinafter, the collet recovery box 111-1 and the collet cartridge 111-2 will be described in detail with reference to FIGS. 5 and 6.

First, as illustrated in FIG. 5, the collet recovery box 111-1 according to the embodiment of the present disclosure is formed in a rectangular parallelepiped shape and includes an opening portion at a bottom side. In this case, the opening portion is formed to load the plurality of recovered collets 300. That is, the plurality of used collets 300 may be loaded onto the collet recovery box 111-1. In this case, a size of the opening portion is larger than a size of the recovered collet 300 in order to easily recover the used collets 300. That is, if a size of the opening portion is equal to a size of the collet 300, the used collet 300 cannot be smoothly recovered.

The collet recovery box 111-1 includes support parts 111-1a and vertical movement parts 111-1b. In this case, the vertical movement part 111-1b is provided rearward of the support part 111-1a and provides power so that the support part 111-1a moves in a vertical direction. In this case, in case that the collet recovery box 111-1 is coupled to the collet accommodation part 111, the support part 111-1a is lowered in the direction perpendicular to a bottom surface, as illustrated in FIG. 5. In case that the collet recovery box 111-1 is coupled to the replacement robot 130 to be described below, the vertical movement part 111-1b operates so that the support part 111-1a is raised and parallel to the bottom surface. With this operation, the completely used collet 300 is seated on the support part 111-1a. When the collet recovery box 111-1 is coupled to the collet accommodation part 111 in the state in which the collet 300 is seated on the support part 111-1a, the support part 111-1a moves perpendicularly to the bottom surface and inserts the completely used collet 300 into the opening portion.

The support part 111-1a includes a bottom member 111-11a, vertical members 111-11b, and inclination members 111-11c. As illustrated in FIG. 5, the support parts 111-1a are installed one by one at the respective sides. First, the bottom member 111-11a includes a surface that allows the completely used collet 300 to be parallel to the bottom surface at a position at which the completely used collet 300 is accommodated. The vertical members 111-11b are provided in the vertical direction on two opposite surfaces of the bottom member 111-11a. In this case, a width of the vertical member 111-11b gradually decreases in the vertical direction, such that a vertex is defined. Further, the inclination member 111-11c has an oblique gradient so as to have a predetermined angle toward the bottom member 111-11a from the vertex of the vertical member 111-11b. Because the two opposite sides of the support part 111-1a are formed as the inclination members 111-11c having predetermined gradients as described above, the used collet 300 may be accurately positioned on the bottom surface when the used collet 300 is introduced into the collet recovery box 111-1. That is, the used collet 300 may be naturally positioned at a center of the collet recovery box 111-1 even though the used collet 300 is not positioned accurately at the center of the collet recovery box 111-1. Because the used collet 300 is positioned at the center of the collet recovery box 111-1 as described above, the used collet 300 may be introduced into the collet recovery box 111-1 when the support part 111-1a moves in the direction perpendicular to the bottom surface.

Next, as illustrated in FIG. 6, the collet cartridge 111-2 according to the embodiment of the present disclosure includes accommodation grooves 111-2a in which the plurality of non-used collets 300 may be loaded, and the collet cartridge 111-2 includes a depressed portion 111-2b, vertical depressed portions 111-2c, inclination portions 111-2d, parallel portions 111-2e, and curved portions 111-2f.

First, as illustrated in FIG. 6, the depressed portion 111-2b has a predetermined size from centers of right and left surfaces of the accommodation groove 111-2a. In this case, the depressed portion includes a surface parallel to the bottom surface. In this case, the vertical depressed portions 111-2c are vertically formed on two opposite surfaces of a parallel surface of the depressed portion 111-2b. As illustrated in FIG. 6, the vertical depressed portion 111-2c has a height smaller than a height by which the depressed portion 111-2b is depressed. Further, the inclination portion 111-2d has a gradient from an end of the vertical depressed portion 111-2c and is formed to a start position of the depressed portion 111-2b. In addition, the parallel portion 111-2e connects the ends of the inclination portions 111-2d and is formed to be parallel to the bottom surface.

Further, the curved portions 111-2f are formed at vertices of the accommodation groove 111-2a and curved in an outward direction of the accommodation groove 111-2a. In this case, as illustrated in FIG. 6, based on the vertex, the curved portion 111-2f is formed in a fan shape having an interior angle of 270 degrees. The curved portion 111-2f may further include a magnet in order to suppress a vibration that occurs when the cabinet unit 110 moves. That is, the magnet may be provided in the curved portion 111-2f and securely support the non-used collet 300.

As described above, the collet cartridge 111-2 is formed to allow the replacement robot 130 to position the collet on an accurate position on the head 400. That is, as illustrated in FIG. 6, the grooves may be formed at the two opposite sides, such that the collet cartridge 111-2 may be accurately positioned on the head 400.

Next, the mounting robot 120 is connected to the ejector. The mounting robot 120 withdraws the completely used ejector hood 200 and moves the completely used ejector hood 200 toward the ejector hood accommodation part 112, and the mounting robot 120 withdraws a non-used ejector hood 200 accommodated in the ejector hood accommodation part 112, moves the non-used ejector hood 200 toward the ejector, and mounts the non-used ejector hood 200. That is, the mounting robot 120 is used to replace the ejector hood 200 that has reached the end of the lifespan. Then, the ejector hood 200 used in the die bonding equipment may be easily replaced.

Next, the replacement robot 130 includes a first replacement robot 131 and a second replacement robot 132. In this case, the first replacement robot 131 is used to withdraw and introduce the collet recovery box 111-1 and the collet cartridge 111-2 positioned on the collet accommodation part 111 or used to move the withdrawn collet recovery box 111-1 toward the second replacement robot 132. That is, as illustrated in FIG. 7, in the state in which the collet recovery box 111-1 or the collet cartridge 111-2 is withdrawn, the first replacement robot 131 moves the collet recovery box 111-1 or the collet cartridge 111-2 toward a lower surface of the head 400 or the second replacement robot 132 while rotating. Further, the second replacement robot 132 receives the

collet recovery box 111-1 from the first replacement robot 131, rotates the received collet recovery box 111-1, and positions the collet recovery box 111-1 on the lower surface of the head 400.

In addition, the first replacement robot 131 and the second replacement robot 132 may provide the operations of raising or lowering the head 400, such that the head 400 may be positioned above the collet recovery box 111-1 and the collet cartridge 111-2.

The operations of the first replacement robot 131 and the second replacement robot 132 will be described. The first replacement robot 131 withdraws the collet recovery box 111-1 and provides the collet recovery box 111-1 to the second replacement robot 132. In the state in which the second replacement robot 132 moves the head 400 upward, the second replacement robot 132 positions the collet recovery box 111-1 below the head 400, introduces the completely used collet into the collet recovery box 111-1, rotates the collet recovery box 111-1 again, and provides the collet recovery box 111-1 to the first replacement robot 131. Then, the first replacement robot 131 loads the collet recovery box 111-1 at the existing original position. As described above, the completely used collet 300 is automatically removed from the head 400.

In addition, the first replacement robot 131 withdraws the collet cartridge 111-2, rotates the collet cartridge 111-2, and positions the collet cartridge 111-2 below the head 400. When the collet 300 with the collet cartridge 111-2 is coupled to the head 400, the first replacement robot 131 introduces the collet cartridge 111-2 into the position at which the collet cartridge 111-2 is withdrawn.

In this case, the head 400 refers to a head, such as a bonding head, a die stage head, or a pick-up head, that may be used at different position.

With the above-mentioned operations, the collets and the ejector hoods may be changed without stopping the operating die bonding equipment or opening a door, thereby maintaining an operation rate of the die bonding equipment.

Further, as illustrated in FIG. 8, in case that the ejector hood 200 or the collet 300 is not replaced, the shutter is closed in the state in which the cabinet unit 110 is positioned in the die bonding equipment. In case that the ejector hood 200 or the collet 300 is replaced, the shutter 118 is opened, and the cabinet unit 110 is withdrawn to the outside.

The present disclosure described with reference to the drawings attached thereto may be variously modified and changed by those skilled in the art, and such modifications and changes, which are not limited by the claims, should be construed as being included in the scope of the present disclosure.

What is claimed is:

1. A supplying/recovering apparatus comprising:
a cabinet unit configured to accommodate a collet and an ejector hood;
a replacement robot configured to withdraw the collet accommodated in the cabinet unit and replace the withdrawn collet; and
a shutter spaced apart from a handle provided in a direction in which the cabinet unit is withdrawn.

2. The supplying/recovering apparatus of claim 1, wherein the cabinet unit comprises:
a collet accommodation part configured to supply and recover the collet;
an ejector hood accommodation part formed at one side of the collet accommodation part and configured to accommodate the ejector hood;
a sliding movement part provided rearward of the collet accommodation part and the ejector hood accommodation part and configured to provide a sliding movement; and
a sliding drive part formed below the collet accommodation part and the ejector hood accommodation part and configured to operate the sliding movement part.

3. The supplying/recovering apparatus of claim 2, wherein the collet accommodation part comprises:
a collet recovery box configured to accommodate a used collet; and
a collet cartridge spaced apart upward from the collet recovery box and configured to accommodate a non-used collet.

4. The supplying/recovering apparatus of claim 3, wherein the collet recovery box comprises:
at least one support part configured to support a lower surface of the used collet; and
a vertical movement part provided on a rear surface of the support part and configured to provide a vertical movement of the support part.

5. The supplying/recovering apparatus of claim 4, wherein the support part comprises:
a bottom member;
vertical members vertically formed on two opposite surfaces of the bottom member and having a width that decreases in a vertical direction; and
an inclination member formed to have a predetermined angle toward the bottom member from a vertex of the vertical member.

6. The supplying/recovering apparatus of claim 3, wherein the collet cartridge comprises:
an accommodation groove;
a depressed portion having a predetermined size from centers of right and left surfaces of the accommodation groove;
vertical depressed portions vertically formed on two opposite surfaces of the depressed portion;
an inclination portion formed to have a gradient from an end of the vertical depressed portion; and
a parallel portion formed to be parallel to a bottom surface from an end of the inclination portion.

7. The supplying/recovering apparatus of claim 6, further comprising:
curved portions respectively formed at vertices of the accommodation groove and curved in an outward direction of the accommodation groove.

8. The supplying/recovering apparatus of claim 3, wherein the replacement robot comprises a first replacement robot and a second replacement robot, the first replacement robot withdraws the collet recovery box and provides the collet recovery box to the second replacement robot, and the second replacement robot moves a head upward, introduces a completely used collet into the collet recovery box, and provides the collet to the first replacement robot.

9. The supplying/recovering apparatus of claim 8, wherein the first replacement robot withdraws the collet cartridge, rotates the collet cartridge, and positions the collet cartridge below the head, and
wherein when the collet with the collet cartridge is coupled to the head, the first replacement robot introduces the collet cartridge into a position at which the collet cartridge is withdrawn.

10. The supplying/recovering apparatus of claim 2, wherein the cabinet unit comprises:
a first base provided with the sliding movement part; and
a second base to which the other side of the sliding movement part is coupled, and
wherein the sliding movement part is provided as a plurality of sliding movement parts.
